(19) United States
(12) Patent Application Publication
(10) Pub. No.: US 2024/0267004 A1
(43) Pub. Date: Aug. 8, 2024

(54) POWER AMPLIFIER

(71) Applicant: Samsung Electro-Mechanics Co., Ltd., Suwon-si (KR)

(72) Inventors: Shinichi IIZUKA, Suwon-si (KR); Youngwong JANG, Suwon-si (KR); Jongok HA, Suwon-si (KR); Hyejin LEE, Suwon-si (KR); Jeonghoon KIM, Suwon-si (KR)

(73) Assignee: Samsung Electro-Mechanics Co., Ltd., Suwon-si (KR)

(21) Appl. No.: 18/497,004

(22) Filed: Oct. 30, 2023

(30) Foreign Application Priority Data
Feb. 3, 2023 (KR) 10-2023-0015110

(51) Int. Cl. H03F 1/02; H03F 1/56; H03F 3/24

(52) U.S. Cl. CPC H03F 1/0222; H03F 1/56; H03F 3/245; H03F 2200/451

(57) ABSTRACT

A power amplifier is provided. The power amplifier includes a power transistor configured to amplify and output an input radio frequency (RF) signal; a first transistor including a first terminal that provides a bias current to the power transistor; and a second transistor including a first terminal connected to a control terminal of the first transistor and a control terminal connected to the first terminal of the first transistor. Herein, the second transistor is configured to sink a first current from the control terminal of the first transistor when an output current of the power transistor exceeds a threshold value.

### CROSS-REFERENCE TO RELATED APPLICATION

This application claims the benefit under 35 USC § 119(a) of Korean Patent Application No. 10-2023-0015110 filed on Feb. 3, 2023, in the Korean Intellectual Property Office, the entire disclosure of which is incorporated herein by reference for all purposes.

### BACKGROUND

### 1. Field

The following description relates to a power amplifier.

### 2. Description of the Background

A wireless communication system may apply various digital modulation and demodulation methods based on the evolution of various communication standards. An existing code division multiple access (CDMA) communication system employs a quadrature phase shift keying (QPSK) method, and a wireless LAN depending on an IEEE communication standard employs an orthogonal frequency division multiplexing (OFDM) method. Additionally, recent 3GPP standard standards such as long term evolution (LTE) and LTE-Advanced employ the QPSK method, a quadrature amplitude modulation (QAM) method, and the OFDM method.

A transmission device implemented in a wireless communication system may include a power amplifier that amplifies a radio frequency (RF) signal in order to increase a transmission distance.

When the load impedance of the power amplifier changes, excessive output current flows, which may cause the power amplifier to deliver power beyond a physical limit thereof. Accordingly, it may be necessary to implement a power amplifier that stably operates even in a situation where an output current exceeds a desired limit.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a power amplifier includes a power transistor configured to amplify an input radio frequency (RF) signal; a first transistor comprising a first terminal that provides a bias current to the power transistor; and a second transistor comprising a first terminal connected to a control terminal of the first transistor, and a control terminal connected to the first terminal of the first transistor, wherein the second transistor is configured to sink a first current from the control terminal of the first transistor when an output current of the power transistor exceeds a threshold value.

The second transistor may be configured to operate when the output current of the power transistor exceeds the threshold value.

The second transistor may be configured to not operate and is configured to not sink the first current from the control terminal of the first transistor when the output current of the power transistor does not exceed the threshold value.

The power amplifier may include a first resistor connected between the control terminal of the second transistor and the first terminal of the first transistor.

The power amplifier may include a second resistor connected between the first terminal of the first transistor and an input terminal of the power transistor.

The power amplifier may include a third resistor connected between a second terminal of the second transistor and ground.

The power amplifier may include a diode connected between the control terminal of the first transistor and ground, wherein a reference current may be applied to a node between the control terminal of the first transistor and the diode.

The first current may increase corresponding to the output current when the output current exceeds the threshold value.

The bias current may be reduced by the first current, and the output current may be reduced based on a decrease in the bias current.

The first terminal of the first transistor may be an emitter and the control terminal of the first transistor is a base, and the control terminal of the second transistor may be a base and the first terminal of the second transistor is a collector.

The control terminal of the second transistor may be connected to an input terminal of the power transistor.

In a general aspect, a power amplifier includes a power transistor; a bias circuit comprising a first transistor configured to provide a bias current to an input terminal of the power transistor; and a current limiting circuit configured to reduce the bias current when an output current of the power transistor exceeds a threshold value, wherein the current limiting circuit includes: a second transistor comprising a collector connected to a base of the first transistor and a base connected to the input terminal of the power transistor.

The current limiting circuit may further include a first resistor connected to the base of the second transistor and an emitter of the first transistor.

The second transistor may be configured to sink a first current from the base of the first transistor when the output current exceeds the threshold value, and the bias current may be reduced by the first current, and the output current may be reduced by a decrease in the bias current.

In a general aspect, a power amplifier includes a bias circuit, comprising a first transistor; a current limiting circuit comprising a current limiting transistor; and a power transistor; wherein a collector of the current limiting transistor is connected to a base of the first transistor, a base of the current limiting transistor is connected to an emitter of the first transistor and an input terminal of the power transistor, and the current limiting transistor is configured to generate a sink current to reduce a bias current of the power transistor when an output current of the power transistor exceeds a threshold value.

The power amplifier may further include a resistor connected between the base of the current limiting transistor and an emitter of the first transistor.

The first transistor may be configured to transmit the bias current to the power transistor.

Other features and examples will be apparent from the following detailed description, the drawings, and the claims.

### BRIEF DESCRIPTION OF DRAWINGS

FIG. 1 illustrates an example power amplifier, in accordance with one or more embodiments.

FIG. 2 illustrates a circuit diagram showing specific configurations of a bias circuit and a current limiting circuit of FIG. 1.

FIG. 3A illustrates an operating state of an example power amplifier when a current limiting circuit does not operate.

FIG. 3B illustrates an operating state of an example power amplifier when a current limiting circuit operates.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto. The use of the terms “example” or “embodiment” herein have a same meaning, e.g., the phrasing “in one example” has a same meaning as “in one embodiment”, and “one or more examples” has a same meaning as “in one or more embodiments.”

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Throughout the specification, when a component or element is described as being “on”, “connected to,” “coupled to,” or “joined to” another component, element, or layer it may be directly (e.g., in contact with the other component, element, or layer) “on”, “connected to,” “coupled to,” or “joined to” the other component, element, or layer or there may reasonably be one or more other components, elements, layers intervening therebetween. When a component, element, or layer is described as being “directly on”, “directly connected to,” “directly coupled to,” or “directly joined” to another component, element, or layer there can be no other components, elements, or layers intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

One or more examples may provide a power amplifier that limits excessive output current.

In accordance with the one or more examples, an output current of a power amplifier may be limited through a current limiting circuit having a simple structure.

Throughout the specification, an RF signal includes Wi-Fi (IEEE 802.11 family, etc.), WiMAX (IEEE 802.16 family, etc.), IEEE 802.20, long term evolution (LTE), Evolution-Data Optimized (Ev-DO), high-speed packet access plus (HSPA+), high-speed downlink packet access plus (HSDPA+), high-speed uplink packet access plus (HSUPA+), Enhanced Data GSM Evolution (EDGE), Global System for Mobile Communications (GSM), Global Positioning System (GPS), General Packet Radio Service (GPRS), Code Division Multiple Access (CDMA), Time Division Multiple Access (TDMA), digital enhanced cordless communication (DECT), Bluetooth, third generation (3G), fourth generation (4G), fifth generation (5G), and any other wireless and wired protocols designated thereafter, but is not limited thereto.

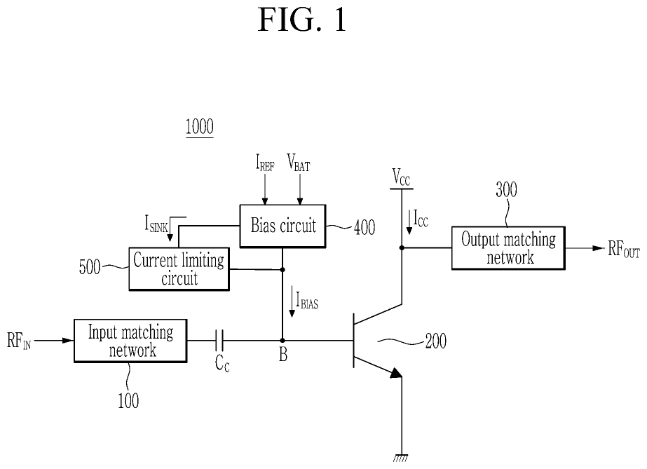

FIG. 1 illustrates an example power amplifier 1000, in accordance with one or more embodiments.

As illustrated in FIG. 1, the example power amplifier 1000 according to an embodiment may include an input matching network 100, a power transistor 200, an output matching network 300, a bias circuit 400, and a current limiting circuit 500.

The input matching network 100 may be connected to an input terminal B (i.e., a base) of the power transistor 200, and may perform impedance matching between an input radio frequency (RF) signal RF_{IN} and the power transistor 200. The output matching network 300 may be connected to an output terminal (i.e., collector) of the power transistor 200, and may perform impedance matching between an output RF signal RF_{OUT} and a next stage (i.e., next stage of the power amplifier).

In a non-limiting example, the input matching network 100 and the output matching network 300 may each be implemented as a combination of at least one of a resistor, an inductor, and a capacitor.

The power transistor 200 may amplify the power of the RF signal RF_{IN} inputted to the input terminal B, and then may output the amplified power to the output terminal (i.e., collector) of the power transistor 200. That is, the base of the power transistor 200 may receive an RF signal to be amplified, and the collector of the power transistor 200 may output the amplified RF signal. An emitter of the power transistor 200 may be connected to ground, and although not illustrated in FIG. 1, a resistor may be additionally connected between the emitter of the power transistor 200 and the ground. A collector of the power transistor 200 may be connected to the power supply voltage V_{CC}, and the power transistor 200 may be operated by the power supply voltage V_{CC}.

Referring to FIG. 1, a current flowing through the output terminal (i.e., collector) of the power transistor 200 is expressed as I_{CC}. In an example, the current I_{CC} may be an output current of the power amplifier 1000. In an example, the collector of the power transistor 200 may be connected to the power supply voltage V_{CC} through an inductor (not shown in FIG. 1) that operates as an RF choke.

In an example, the power transistor 200 may be implemented with various transistors such as, but not limited to, a heterojunction bipolar transistor (HBT), a bipolar junction transistor (BJT), and an insulated gate bipolar transistor (IGBT). Additionally, although the power transistor 200 is illustrated as an n-type in FIG. 1, this is only an example, and the power transistor 200 may be implemented as a p-type.

In an example, a coupling capacitor C_{C} may be connected to the input terminal (i.e., base) of the power transistor 200. The coupling capacitor Cc may perform an operation of blocking a direct current (DC) component from an RF signal.

The bias circuit 400 may receive a reference current I_{REF} and a power supply voltage V_{BAT} from external sources. In an example, the power source voltage V_{BAT} may be a voltage that is supplied from the battery. The bias circuit 400 may generate a bias current I_{BIAS} that may be desired by the power transistor 200 based on the reference current I_{REF} and the power supply voltage V_{BAT}. The bias current I_{BIAS} may be supplied to the input terminal B of the power transistor 200, and a bias level (bias point) of the power transistor 200 may be set by the bias current I_{BIAS}.

In an example, in an abnormal state, the output current I_{CC} may occur in excess. An example of an abnormal state may be an example where load impedance of the power transistor 200 fluctuates greatly. When human contact or the like occurs in an antenna connected to the power amplifier 1000, the load impedance may be lowered. Accordingly, the output current I_{CC} may be excessively increased. When the output current I_{CC} is excessively increased, the power transistor 200 may be damaged or destroyed. The current limiting circuit 500, in accordance with one or more embodiments, may limit the bias current I_{BIAS} when the output current I_{CC} is excessively increased. The output current I_{CC} may be reduced by limiting the bias current I_{BIAS}.

Hereinafter, an example in which the output current I_{CC} is excessively increased will be described by assuming that the output current I_{CC} exceeds a threshold value. In an example, the threshold value may be preset according to an implementation of the power amplifier 1000.

The current limiting circuit 500 may be connected to the bias circuit 400, and a determination of whether the current limiting circuit 500 operates may be based on a magnitude of the output current I_{CC}.

In an example, when the output current I_{CC} does not exceed the threshold value, the current limiting circuit 500 may not operate. That is, when the output current I_{CC} does not exceed the threshold value, the current limiting circuit 500 may be turned off.

When the output current I_{CC} exceeds the threshold value, the current limiting circuit 500 may operate and generate a sink current I_{SINK}. That is, when the output current I_{CC} exceeds the threshold value, the current limiting circuit 500 may be turned on. In an example, the current limiting circuit 500 may sink (subtract) as much as the sink current I_{SINK} from a current generated in the bias circuit 400. The bias current I_{BIAS} of the bias circuit 400 may be reduced by the sink current I_{SINK}. A specific configuration and operation of the current limiting circuit 500 will be described in detail below.

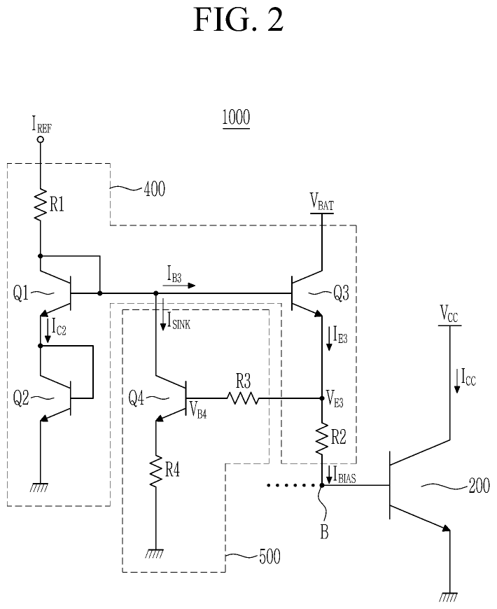

FIG. 2 illustrates a circuit diagram showing specific configurations of the bias circuit 400 and the current limiting circuit of FIG. 1.

As illustrated in FIG. 2, the bias circuit 400 may include a transistor Q1, a transistor Q2, a transistor Q3, a resistor R1, and a resistor R2.

The transistors Q1 to Q3, may be implemented with various transistors such as, but not limited to, a heterojunction bipolar transistor (HBT), a bipolar junction transistor (BJT), and an insulated bipolar transistor (IGBT). Additionally, although the transistors Q1 to Q3 are illustrated as an n-type in FIG. 2, this is only an example, and the transistors Q1 to Q3 may be p-type transistors. In an example, since the bases of the transistors Q1 to Q3 may be control terminals, the term ‘control terminal’ may be used. Since the collectors of the transistors Q1 to Q3 may be one terminal of the transistor, the term ‘first terminal or second terminal’ may be used. Additionally, since the emitters of the transistors Q1 to Q3 may also be one terminal of the transistor, the term ‘first terminal or second terminal’ may be used.

The base and the collector of the transistor Q1 may be connected to each other, and the collector of the transistor Q1 may receive the reference current I_{REF} through the resistor R1. In an example, the transistor Q1 may have a diode connection structure. The transistor Q1 may operate to sink a current I_{C2} from the reference current I_{REF}. In an example, the reference current I_{REF} may be a current source.

The base and the collector of the transistor Q2 may be connected to each other, and the collector of the transistor Q2 may be connected to the emitter of the transistor Q1. In an example, the transistor Q2 may have a diode connection structure, and the emitter of the transistor Q2 may be connected to ground. In an example, although not illustrated in FIG. 2, a resistor may be added between the emitter of the transistor Q2 and ground.

The collector of the transistor Q3 may be connected to a power voltage V_{BAT}, and the base of the transistor Q3 may be connected to the base of the transistor Q1. Additionally, the emitter of the transistor Q3 may be connected to the input terminal B of the power transistor 200 through the resistor R2. That is, the emitter of the transistor Q3 may supply the bias current I_{BIAS} to the power transistor 200 through the resistor R2. In an example, the resistor R2 may be omitted. That is, the emitter of the transistor Q3 may be connected to the input terminal B (i.e., base) of the power transistor 200.

In FIG. 2, a base current of the transistor Q3 is denoted by I_{B3}, an emitter current of the transistor Q3 is denoted by I_{E3}, and an emitter voltage of the transistor Q3 is denoted by V_{E3}.

As illustrated in FIG. 2, the current limiting circuit 500, in accordance with one or more embodiments, may include a transistor Q4, a resistor R3, and a resistor R4.

The transistor Q4 may be implemented with various transistors such as, but not limited to, a heterojunction bipolar transistor (HBT), a bipolar junction transistor (BJT), and an insulated bipolar transistor (IGBT). Additionally, although the transistor Q4 is illustrated as an n-type in FIG. 2, this is only an example, and the transistor Q4 may be a p-type.

In an example, since a base of the transistor Q4 may operate as a control terminal, the term ‘control terminal’ may be used. Since a collector of the transistor Q4 may operate as one terminal of the transistor, the term ‘first terminal or second terminal’ may be used. Additionally, since an emitter of the transistor Q4 may operate as one terminal of the transistor, the term ‘first terminal or second terminal’ may be used.

The collector of the transistor Q4 may be connected to the base of the transistor Q3, and the emitter of the transistor Q4 may be connected to ground through the resistor R4. The base of the transistor Q4 may be connected to the emitter of the transistor Q3 through the resistor R3. In an example, the resistor R3 may be omitted. That is, in an example, the base of the transistor Q4 may be connected to the input terminal B (i.e., base) of the power transistor 200, and the base of the transistor Q4 may be connected to the emitter of the transistor Q3. In FIG. 2, a base voltage of the transistor Q4 is indicated by V_{B4}.

The resistor R4 may be connected between the emitter of the transistor Q4 and ground. Additionally, the resistor R3 may be connected between the base of the transistor Q4 and the emitter of the transistor Q3. In an example, the resistors R3 and R4 may be omitted.

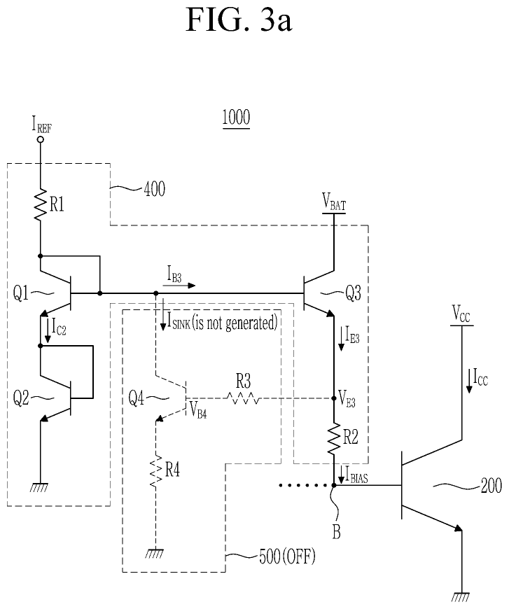

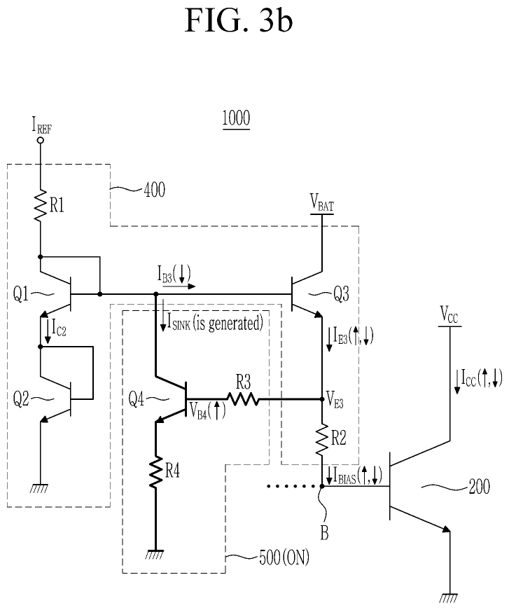

FIG. 3A illustrates an operating state of the power amplifier 1000 when the current limiting circuit 500 does not operate.

When the output current I_{CC} does not exceed the threshold value, the current limiting circuit 500 does not operate. That is, when the output current I_{CC} is within a normal range, the transistor Q4 of the current limiting circuit 500 may not operate. When the output current I_{CC} is within the normal range, the bias current I_{BIAS} also has a value in the normal range. In this example, an emitter voltage V_{E3} of the transistor Q3 may have a small value, which may cause the transistor Q4 to not operate. Since the transistor Q4 is not operated, the current limiting circuit 500 may be turned off. In other words, when the output current I_{CC} does not exceed a threshold value, the current limiting circuit 500 does not generate the sink current I_{SINK}.

The reference current I_{REF} may be divided by the current I_{C2} and the base current I_{B3} of the transistor Q3, and the base current I_{B3} of the transistor Q3 may be inputted to the base of the transistor Q3. The transistor Q3 generates the emitter current les of the transistor Q3 in response to the base current I_{B3} of the transistor Q3. In an example, since the current limiting circuit 500 does not operate, the emitter current les of the transistor Q3 may operate as the bias current I_{BIAS}. Since the bias current I_{BIAS} corresponds to the base current of the power transistor 200, the bias current I_{BIAS} and the output current I_{CC} may have a relationship of Equation 1 below.

$${I}_{BIAS} = \frac{{I}_{CC}}{β} \qquad Equation 1$$

In Equation 1 above, β indicates a common-emitter current gain of the power transistor 200. Referring to Equation 1, the bias current I_{BIAS} may increase in proportion to the output current I_{CC}.

FIG. 3B illustrates an operating state of the power amplifier 1000 when the current limiting circuit 500 operates. In FIG. 3B, 1 represents an increase in current, and ⬇ represents a decrease in current.

When the output current I_{CC} does not exceed a threshold value, the current limiting circuit 500 does not operate. That is, when the output current I_{CC} is increased beyond an abnormal range, the current limiting circuit 500 may start operating.

Referring to Equation 1 above, when the output current I_{CC} increases, the bias current I_{BIAS} increases. When the bias current I_{BIAS} increases, an emitter current I_{E3} of the transistor Q3 also increases. An emitter voltage V_{E3} of the transistor Q3 will also increase by an increase of the emitter current les of the transistor Q3. As the emitter voltage V_{E3} of the transistor Q3 increases, a base voltage V_{B4} of the transistor Q4 also increases, and the transistor Q4 is turned on.

In an example, the emitter voltage V_{E3} of the transistor Q3 and the base voltage V_{B4} of the transistor Q4 may be high enough voltages to operate the transistor Q4. That is, the transistor Q4 may be turned on. When the transistor Q4 is turned on, a sink current I_{SINK} is generated. In other words, when the output current I_{CC} exceeds a threshold value, the current limiting circuit 500 generates the sink current I_{SINK}.

In an example, the reference current I_{REF}, the current I_{C2}, the base current I_{B3} of the transistor Q3, and the sink current I_{SINK} may have a relationship of Equation 2 below.

$${I}_{REF} = {I}_{C 2} + {I}_{B 3} + {I}_{SINK} \qquad Equation 2$$

In Equation 2, assuming that the reference current I_{REF} and the current I_{C2} are fixed values, the base current I_{B3} and the sink current I_{SINK} of the transistor Q3 may have values in inverse proportion to each other. That is, when the sink current I_{SINK} is not generated and then is generated, the base current I_{B3} of the transistor Q3 is reduced. Additionally, when the sink current I_{SINK} increases, the base current I_{B3} of the transistor Q3 decreases.

In other words, when the output current I_{CC} exceeds the threshold, the current limiting circuit 500 generates the sink current I_{SINK}, and thus the base current I_{B3} of the transistor Q3 may decrease. When the output current I_{CC} exceeds a threshold value, the current limiting circuit 500 generates the sink current I_{SINK}, and thus the base current I_{B3} of the transistor Q3 may decrease. As the emitter current les of the transistor Q3 decreases, the bias current I_{BIAS} decreases, resulting in a final decrease in the output current I_{CC}. Accordingly, as the output current I_{CC} decreases, the output current I_{CC} may return to a normal range. That is, when the output current I_{CC} exceeds the threshold value, the current limiting circuit 500 may generate a sink current to limit the output current I_{CC} to the normal range.

While this disclosure includes specific examples, it will be apparent to one of ordinary skill in the art, after an understanding of the disclosure of this application, that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A power amplifier, comprising:
a power transistor configured to amplify an input radio frequency (RF) signal;
a first transistor comprising a first terminal that provides a bias current to the power transistor; and
a second transistor comprising a first terminal connected to a control terminal of the first transistor, and a control terminal connected to the first terminal of the first transistor,
wherein the second transistor is configured to sink a first current from the control terminal of the first transistor when an output current of the power transistor exceeds a threshold value.

2. The power amplifier of claim 1, wherein the second transistor is configured to operate when the output current of the power transistor exceeds the threshold value.

3. The power amplifier of claim 2, wherein the second transistor is configured to not operate and is configured to not sink the first current from the control terminal of the first transistor when the output current of the power transistor does not exceed the threshold value.

4. The power amplifier of claim 1, further comprising a first resistor connected between the control terminal of the second transistor and the first terminal of the first transistor.

5. The power amplifier of claim 4, further comprising a second resistor connected between the first terminal of the first transistor and an input terminal of the power transistor.

6. The power amplifier of claim 5, further comprising a third resistor connected between a second terminal of the second transistor and ground.

7. The power amplifier of claim 1, further comprising:
a diode connected between the control terminal of the first transistor and ground,
wherein a reference current is applied to a node between the control terminal of the first transistor and the diode.

8. The power amplifier of claim 1, wherein the first current increases corresponding to the output current when the output current exceeds the threshold value.

9. The power amplifier of claim 1, wherein:
the bias current is reduced by the first current, and
the output current is reduced based on a decrease in the bias current.

10. The power amplifier of claim 1, wherein:
the first terminal of the first transistor is an emitter and the control terminal of the first transistor is a base, and
the control terminal of the second transistor is a base and the first terminal of the second transistor is a collector.

11. The power amplifier of claim 1, wherein the control terminal of the second transistor is connected to an input terminal of the power transistor.

12. A power amplifier, comprising:
a power transistor;
a bias circuit comprising a first transistor configured to provide a bias current to an input terminal of the power transistor; and
a current limiting circuit configured to reduce the bias current when an output current of the power transistor exceeds a threshold value,
wherein the current limiting circuit comprises:
a second transistor comprising a collector connected to a base of the first transistor and a base connected to the input terminal of the power transistor.

13. The power amplifier of claim 12, wherein the current limiting circuit further comprises a first resistor connected to the base of the second transistor and an emitter of the first transistor.

14. The power amplifier of claim 12, wherein:
the second transistor is configured to sink a first current from the base of the first transistor when the output current exceeds the threshold value, and the bias current is reduced by the first current, and the output current is reduced by a decrease in the bias current.

15. A power amplifier, comprising:
a bias circuit, comprising a first transistor;
a current limiting circuit comprising a current limiting transistor; and
a power transistor;
wherein:
a collector of the current limiting transistor is connected to a base of the first transistor,
a base of the current limiting transistor is connected to an emitter of the first transistor and an input terminal of the power transistor, and
the current limiting transistor is configured to generate a sink current to reduce a bias current of the power transistor when an output current of the power transistor exceeds a threshold value.

16. The power amplifier of claim 15, further comprising a resistor connected between the base of the current limiting transistor and an emitter of the first transistor.

17. The power amplifier of claim 15, wherein the first transistor is configured to transmit the bias current to the power transistor.
